(19) United States
(12) Patent Application Publication
(10) Pub. No.: US 2025/0323462 A1
(43) Pub. Date: Oct. 16, 2025

(54) ELECTRICAL CONNECTOR

(71) Applicant: PHOENIX CONTACT GMBH & CO. KG, Blomberg (DE)

(72) Inventors: Karsten Krome, Detmold (DE); Sebastian Stamm, Brakel (DE); Benjamin Monzer, Bad Pyrmont (DE); Ulrich Rosemeyer, Schieder-Schwalenberg (DE)

(21) Appl. No.: 18/865,386

(22) PCT Filed: May 9, 2023
(86) PCT No.: PCT/EP2023/062257

§ 371 Date: Nov. 13, 2024

(30) Foreign Application Priority Data
May 16, 2022 (BE) 2022/5364

(51) Int. Cl. H01R 24/50; H01R 12/70

(52) U.S. Cl. CPC H01R 24/50; H01R 12/707

(57) ABSTRACT

An electrical connector includes: a body having a contact side at which the body is placeable against a printed circuit board; a first conductor with a first section and a second section; and a second conductor with a first section and a second section. The first section of the first conductor and the first section of the second conductor run at a distance from each other. Wherein the second section of the first conductor and the second section of the second conductor together project from the body on the contact side adjacent to one another.

### CROSS-REFERENCE TO PRIOR APPLICATIONS

This application is a U.S. National Phase application under 35 U.S.C. § 371 of International Application No. PCT/EP2023/062257, filed on May 9, 2023, and claims benefit to Belgian Patent Application No. BE 2022/5364, filed on May 16, 2022. The International Application was published in German on Nov. 23, 2023 as WO/2023/222451 under PCT Article 21(2).

### FIELD

The invention relates to an electrical connector and an assembly having such an electrical connector and a printed circuit board.

### BACKGROUND

Electrical connectors, e.g., in the form of electrical plug connector parts, have a wide range of applications. Often, electrical conductors of electrical connectors are connected to a printed circuit board, e.g., soldered to connection fields of the printed circuit board. The printed circuit board can be integrated into the electrical connector. Furthermore, the electrical connector can be designed, for example, in the form of a socket or a built-in plug and can be plugged onto a printed circuit board and soldered thereto.

Electrical connectors should provide consistently good electrical connections over a long period of time. Furthermore, electrical connectors should typically be simple to design and manufacture. Since electrical connectors are often mass-produced products, simplifications in design and manufacture are often particularly important.

### SUMMARY

In an embodiment, the present invention provides an electrical connector, comprising: a body having a contact side at which the body is placeable against a printed circuit board; a first conductor with a first section and a second section; and a second conductor with a first section and a second section, wherein the first section of the first conductor and the first section of the second conductor run at a distance from each other, and wherein the second section of the first conductor and the second section of the second conductor together project from the body on the contact side adjacent to one another.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 shows an electrical connector for mounting on a printed circuit board with a body, a first conductor, and a second conductor;

FIGS. 2A and 2B are sectional views of the electrical connector according to the sectional plane A-A shown in FIG. 1, as well as a printed circuit board;

FIG. 3 is a plan view of a contact side of the body of the electrical connector according to FIG. 1, at which the body can be placed against the printed circuit board;

FIG. 4 is a perspectival view of the contact side of the connector according to FIG. 1;

FIG. 5 is a detail view of the detail section D2 shown in FIG. 4;

FIGS. 6A and 6B show detail views of the detail section D1 shown in FIG. 2A;

FIG. 7 is a perspectival view of the first conductor and the second conductor of the electrical connector according to FIG. 1;

FIG. 8 is a detail view of the detail section D3 shown in FIG. 7;

FIG. 9 is a view of the printed circuit board with the electrical connector connected thereto; and

FIG. 10 is a detail view of the detail section D4 shown in FIG. 9.

### DETAILED DESCRIPTION

In an embodiment, the present invention provides an electrical connector which allows a secure electrical connection with the simplest possible design.

Accordingly, an electrical connector is provided, comprising a body having a contact side at which the body can be placed against a printed circuit board, a first conductor with a first section and a second section, and a second conductor with a first section and a second section. It is provided that the first section of the first conductor and the first section of the second conductor run at a distance from each other, and the second section of the first conductor and the second section of the second conductor together project from the body on the contact side adjacent to one another. In particular, the second sections are closer to each other than the first sections are to each other.

This allows both conductors to be connected to the printed circuit board together, in particular using a single soldering point. This allows a good electrical connection over a long period of time, with a simple design, and also allows for simplified connection, since two connections can be connected at once with just one soldering point.

The second section of the first conductor and the second section of the second conductor are, for example, electrically contacted or contactable and together project from the body on the contact side.

For example, the second section of the first conductor and the second section of the second conductor run parallel to each other. This allows easy threading—for example, through an opening in the printed circuit board. In particular, the second sections adjoin one another.

Optionally, the second section of the first conductor encompasses the second section of the second conductor at least in sections. For example, the second section of the first conductor extends around at least part of the second section of the second conductor. This makes it possible to guide both conductors through a relatively small opening in the printed circuit board. Furthermore, the two conductors can support each other, making it easier to guide the conductors through the opening without either conductor bending.

The second sections of the conductors may touch one another, e.g., touch along their lengths. The second section of the first conductor and the second section of the second conductor are in contact with each other—for example, along a contact line or an elongated contact region. This ensures a particularly secure electrical connection between the two conductors. In addition, the two conductors can thus support each other well. Alternatively, there is a gap between the second sections, and electrical contact can then be made, for example, by soldering. The gap is, for example, smaller than the thickness of the second section of the first conductor and/or the second conductor.

Optionally, the second section of the second conductor (or the first conductor) is coaxial with the first section of the second conductor (or the first conductor). This allows for particularly simple manufacture and assembly of this conductor.

For example, the second section of the second conductor is offset from the first section of the second conductor. Both sections extend along directions parallel to each other. Alternatively or additionally, the second section of the first conductor is offset from the first section of the first conductor.

In one embodiment, the first section of the first conductor is sleeve-shaped. The first section of the first conductor optionally surrounds another conductor (or, prior to installation of the additional conductor, a receptacle for this additional conductor).

The first section of the first conductor may provide shielding, e.g., for another conductor surrounded by the first section of the first conductor. This allows particularly good shielding that can be connected in a simple manner.

The second conductor can be pin-shaped. This allows the electrical connector to be easily manufactured and designed.

The first conductor is optionally made of (in particular consists of) a flat material—for example, by punching and bending a piece of flat material. The flat material can be placed against the second conductor, which is in particular pin-shaped, in a space-saving manner and can also be easily formed into a sleeve.

The electrical connector can be designed in the form of a plug connector part. The electrical connector is therefore, for example, an electrical plug-in connector part. The electrical connector can have plug-in sections which can be electrically connected to mating plug-in sections of a mating plug connector part.

According to one aspect, an electrical assembly is provided comprising a circuit board and at least one electrical connector according to any embodiment described herein. As regards the advantages, reference is made to the above statements regarding the electrical connector.

The printed circuit board has, for example, an opening, e.g., in the form of a hole, wherein in particular the second section of the first conductor and the second section of the second conductor can be inserted together through the opening or are inserted in an assembled state.

The second section of the first conductor and the second section of the second conductor can be soldered together in the assembled state, in particular at the opening, e.g., at an edge region of the opening. This allows a secure electrical and mechanical connection between both conductors and an electrical contact on the printed circuit board.

Optionally, the second section of the first conductor and the second section of the second conductor are soldered together at the opening and are soldered or can be soldered to the printed circuit board.

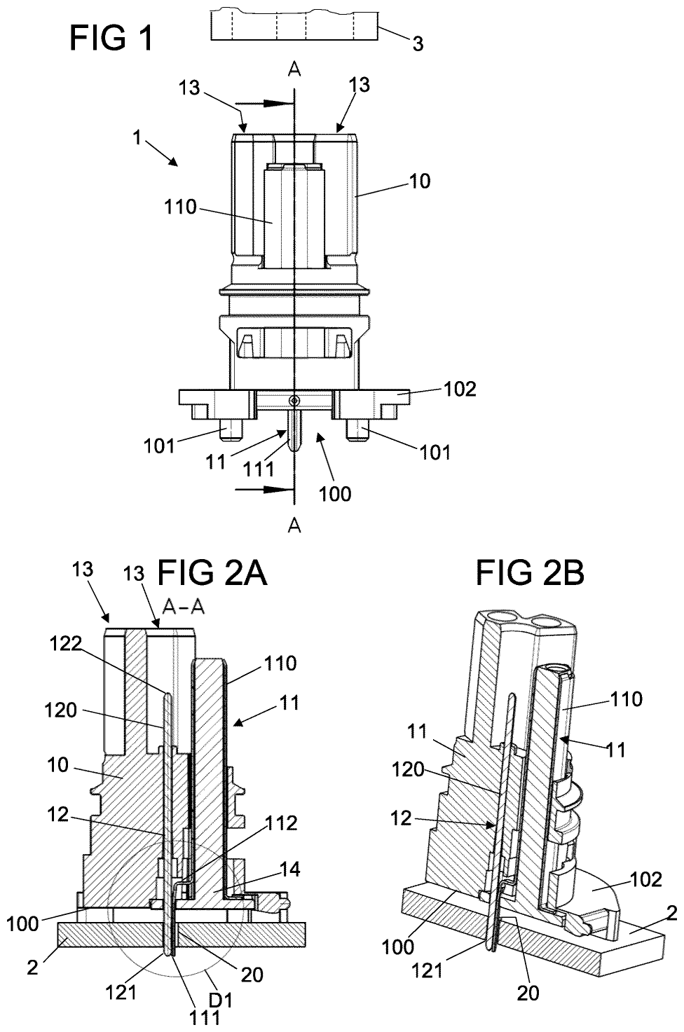

FIG. 1 shows an electrical connector 1 in the form of a plug connector part. The electrical connector 1 can be plugged into a suitable mating plug connector part 3 to establish electrical connections. The electrical connector 1 forms a plug connection with the mating plug connector part 3. The electrical connector 1 is designed as a built-in plug, for example.

The electrical connector 1 comprises a body 10 made of an insulating material, e.g., a plastic, and preferably has a plurality of plug-in sections 13. The plug-in sections 13 can each be connected to a corresponding mating plug-in section of the mating plug connector part 3. An electrical conductor can be mounted on each of the plug-in sections 13 and is mounted in the assembled state.

The body 10 of the electrical connector 1 has a contact side 100, at which the body 10 can be placed against a printed circuit board 2, as illustrated, for example, in FIGS. 2A and 2B.

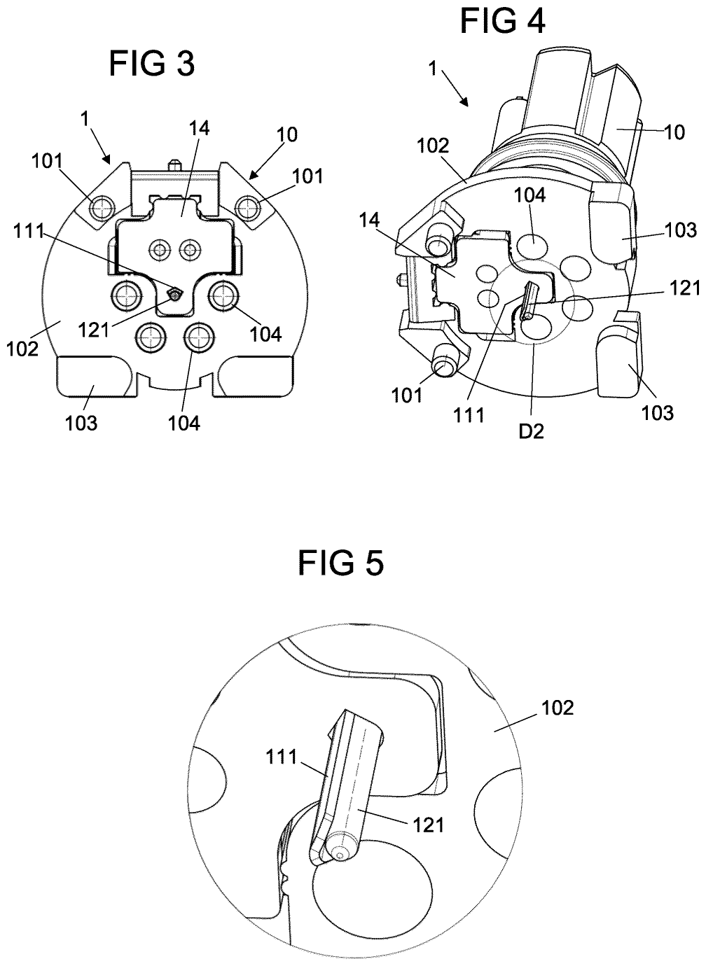

Feet 103 on the contact side 100 serve to ensure a secure and wobble-free position of the electrical connector 1 on the printed circuit board 2 and form a distance to the form of the soldering point on the top side of the printed circuit board. Positioning pins 101 on the contact side 100 serve to position the electrical connector 1 with the correct orientation on the printed circuit board 2 (see, for example, FIGS. 3, 4, and 9). The body 10 has a base 102 which defines the contact side 100. The base 102 has an enlarged cross-section compared to the rest of the body 10. This ensures a particularly secure and robust position of the electrical connector 1. The feet 103 are formed on the base 102. The positioning pins 101 are formed on the base 102.

The electrical connector 1 further comprises a first electrical conductor 11 and a second electrical conductor 12 (and optionally further electrical conductors). The first conductor 11 has a first section 110 and a second section 111. The second conductor 12 also has a first section 120 and a second section 121. It is provided that the first section 110 of the first conductor 11 and the first section 120 of the second conductor 12 run at a distance from each other and that the second section 111 of the first conductor 11 and the second section 121 of the second conductor 12 be electrically contacted with one another or be contactable and together project from the body 10 on the contact side 100 directly adjacent to one another. In the present case, the second sections 111, 121 touch one another. The second section 111 of the first conductor 11 and the second section 121 of the second conductor 12 touch one another and together project from the body 10 on the contact side 100.

The first section 110 and the second section 111 of the first conductor 11 are electrically connected to each other. The first conductor 11 is formed in one piece. The first section 120 and the second section 121 of the second conductor 12 are electrically connected to each other. The second conductor 12 is formed in one piece.

It should be noted at this point that the electrical connector 1 may also comprise more than two conductors 11, 12 arranged in this way. For example, a third conductor could be provided with a first section spaced from the other first sections 110, 120 and a second section in contact with the other second sections 111, 121. Alternatively or additionally, one or more further pairs of first and second conductors, each arranged as described above, may be provided.

As can be seen in particular from FIGS. 2A, 2B, and 7, the second conductor 12 extends in a straight line (along a direction that runs parallel to an insertion direction along which the electrical connector and the mating plug connector part can be plugged into one another). The second section 121 of the second conductor 12 is aligned coaxially with the first section 120 of the second conductor 12. The second conductor 12 is pin-shaped. The first section 120 of the second conductor 12 has one longitudinal end of the second conductor 12, and the second section 121 has the other longitudinal end of the second conductor 12. The end of the first section 120 of the second conductor forms a plug contact 122 for a corresponding mating plug contact of the mating plug connector part 3. The end of the second section 121 of the second conductor 12 forms a solder pin for soldering to the printed circuit board 2. The second section 121 of the second conductor 12 projects far enough from the contact side 100 that, in the assembled state, it extends through an opening 20 in the printed circuit board 2 (see, for example, FIGS. 2A, 2B, 9, and 10). The opening 20 is a bore or a through-hole in the printed circuit board.

The second conductor 12 represents, for example, a shield contact. For example, the second conductor 12, in the assembled state, is electrically connected to a shield, earth, and/or ground potential of the printed circuit board 2.

The first section 110 of the first conductor 11 is sleeve-shaped (see in particular FIGS. 7 and 8). The first section 110 of the first conductor 11 is elongated and aligned parallel to the second conductor 12. The first section 110 of the first conductor 11 serves as a shielding sleeve. The first section 110 of the first conductor 11, designed as a shielding sleeve, protects two data contacts from interference from surrounding power contacts or external interference. For this purpose, the first section 110 of the first conductor 11 surrounds two plug openings of the electrical connector 1, in each of which an electrical conductor is arranged in the assembled state.

The second section 111 of the first conductor 11 is arranged offset from the first section 110 of the first conductor 11. The second section 111 of the first conductor 11 also runs parallel to the second conductor 12. The second section 111 of the first conductor 11 is arranged offset from the first section 110 of the first conductor 11 in a direction that is perpendicular to the orientation of the first section 110 and the second section 111 of the first conductor 11. For this purpose, the first conductor 11 has an offset 112 which electrically conductively connects the first section 110 to the second section 111. In addition, the first conductor has a tab, opposite the offset 112, which is mirror-imaged to the offset 112, but has an open end. In the assembled state, the first conductor 11 is supported by the offset 112 and the tab on the body 10. The offset 112 merges into the second section 111 of the first conductor 11.

In particular, FIG. 8 illustrates that the second section 111 of the first conductor 11 lies flat against the second section 121 of the second conductor 12. Specifically, the second section 111 of the first conductor 11 encompasses the second section 121 of the second conductor 12 over a part of the circumference of the second conductor 12, as can also be seen in FIG. 10. This configuration allows a particularly good electrical contact between the two conductors 11, 12, and a joint insertion of the two conductors 11, 12 into a relatively small opening 20 of the printed circuit board 2.

The first conductor 11 is made of a flat material, e.g., a metal sheet, specifically by punching and bending.

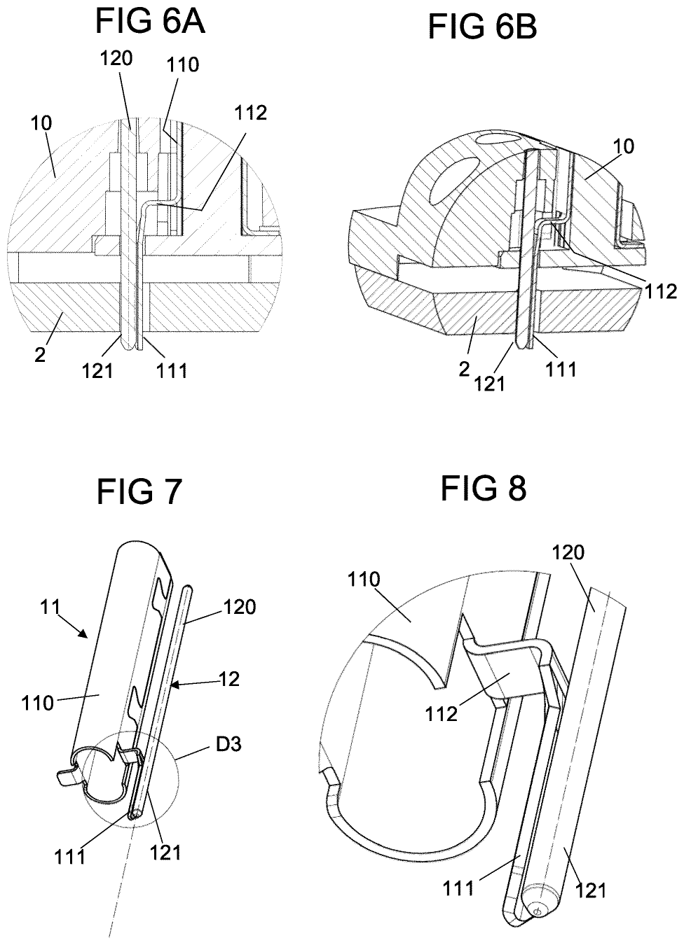

During the manufacture of the electrical connector 1, the first conductor 11 is inserted into an opening of the body 10. An insert 14 is inserted into the first section 110 of the first conductor 11. As a result, the first conductor 11 is fixed to the body 10, wherein the offset 14 and the tab are locked between the body 10 and the insert 14, as can be seen in particular from FIGS. 6A and 6B. The offset 112 forms a step.

The insert 14 has two openings for one data contact each and one opening for the second sections 111, 121 of the first and second conductors 11, 12. In the body 10, there are further openings 104 (specifically, four) for one data or power contact each; see, for example, FIGS. 3 and 4.

In particular, it can be seen from FIGS. 1, 4, and 5 that the second sections of the first conductor 11 and the second conductor 12 project vertically from the contact side 100.

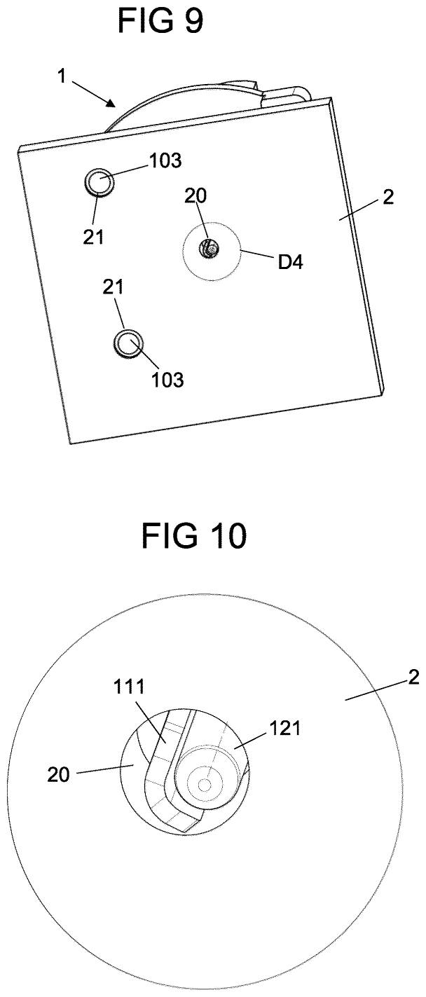

FIGS. 9 and 10 show a view of the underside of the printed circuit board 2 with the mounted electrical connector 1. The positioning pins 101 each extend through an opening 21 of the printed circuit board 2. The second sections 110, 120 of the first conductor 11 and the second conductor 12 pass through the opening 20 of the printed circuit board 2 and can thus be soldered to a corresponding electrical connection field of the printed circuit board 2. In this case, only a single soldering process is sufficient for both conductors 11, 12, which also reduces the work required for the connection. In addition, only one hole is required in the printed circuit board 2 for both conductors, and only one hole needs to be filled with a paste if necessary, only one hole is required in a paste mask instead of two holes, and so on. Furthermore, more layout space is available on the printed circuit board 2. In addition, the connection field of the electrical connector 1 can be simplified. The solder securely electrically contacts the second sections 111, 121 with each other. The second sections 111, 121 thus provide contact zones. It is sufficient if the second sections 111, 121 project close to each other from the contact side 100, since, at the latest, the solder establishes the electrical connection.

A further advantage is that a plurality of electrical potentials, e.g., ground, shield, and/or earth potentials, are transferred to the printed circuit board 2 at exactly one location.

This allows a space-saving assembly with a simple and cost-effective design. In addition, such a joint soldering is also particularly stable and resistant in the long run, in contrast to many electrical contacts made by spring force, for example, which are typically more susceptible to aging and corrosion processes.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

1 Electrical connector
10 Body
100 Contact side
101 Positioning pin
102 Base
103 Foot
104 Opening
11 First conductor
110 First section
111 Second section
112 Offset
12 Second conductor
120 First section
121 Second section
122 Plug contact
13 Plug-in section
14 Insert
2 Printed circuit board
20 Opening
21 Opening
3 Mating plug connector part

1: An electrical connector, comprising:
a body having a contact side at which the body is placeable against a printed circuit board;
a first conductor with a first section and a second section; and
a second conductor with a first section and a second section,
wherein the first section of the first conductor and the first section of the second conductor run at a distance from each other, and
wherein the second section of the first conductor and the second section of the second conductor together project from the body on the contact side adjacent to one another.

2: The electrical connector of claim 1, wherein the second section of the first conductor and the second section of the second conductor are electrically contacted with one another or are contactable and together project from the body on the contact side.

3: The electrical connector of claim 1, wherein the second section of the first conductor and the second section of the second conductor run parallel to each other.

4: The electrical connector of claim 1, wherein the second section of the first conductor encompasses the second section of the second conductor at least in sections.

5: The electrical connector of claim 1, wherein the second section of the first conductor and the second section of the second conductor are in contact with each other along a contact line or an elongated contact region.

6: The electrical connector of claim 1, wherein the second section of the second conductor is coaxial with the first section of the second conductor.

7: The electrical connector of claim 1, wherein the second section of the first conductor is offset from the first section of the first conductor.

8: The electrical connector of claim 1, wherein the first section of the first conductor is sleeve-shaped.

9: The electrical connector of claim 1, wherein the first section of the first conductor is configured to provide shielding.

10: The electrical connector of claim 1, wherein the second conductor is pin-shaped.

11: The electrical connector of claim 1, wherein the first conductor comprises a flat material.

12: The electrical connector of claim 1, wherein the electrical connector comprises a plug connector part and has plug-in sections electrically connectable to mating plug-in sections of a mating plug connector part.

13: An electrical assembly, comprising:
a printed circuit board;
the electrical connector of claim 1.

14: The electrical assembly of claim 13, wherein the printed circuit board has an opening, and
wherein the second section of the first conductor and the second section of the second conductor are inserted or insertable together through the opening.

15: The electrical assembly of claim 14, wherein the second section of the first conductor and the second section of the second conductor are soldered together at the opening.

16: The electrical assembly of claim 1, wherein the second section of the first conductor and the second section of the second conductor are soldered together at the opening and are soldered or solderable to the printed circuit board.
